(19) United States
(12) Patent Application Publication
(10) Pub. No.: US 2007/0175495 A1
(43) Pub. Date: Aug. 2, 2007

(54) Apparatus for Treating Plasma and Method for Cleaning the Same

(76) Inventors: Weon-Hong Kim, Suwon-si (KR); Seok-Jun Won, Seoul (KR); Dae-Jin Kwon, Suwon-si (KR); Min-Woo Song, Seongnam-si (KR); Ju-Youn Kim, Suwon-si (KR); Jung-Min Park, Ansan-si (KR)

Correspondence Address: F. CHAU & ASSOCIATES, LLC, 130 WOODBURY ROAD, WOODBURY, NY, 11797, US

(21) Appl. No.: 11/668,805

(22) Filed: Jan. 30, 2007

(30) Foreign Application Priority Data
Feb. 2, 2006 (KR) 2006-10098

(51) Int. Cl. B08B 6/00; C23F 1/00; C23C 16/00

(52) U.S. Cl. 134/1.2; 118/723 E; 156/345.3

(57) ABSTRACT

An apparatus for treating plasma includes an inner chamber, an outer chamber receiving the inner chamber and including a gas supplier that supplies a gas into the inner chamber, an inner electrode disposed in the inner chamber, and a plasma generator supplying power independently to the inner electrode and the inner chamber.

### CROSS-REFERENCE TO RELATED APPLICATIONS

This U.S. non-provisional patent application claims priority under 35 U.S.C. § 119 of Korean Patent Application No. 2006-10093, filed on Feb. 2, 2006, the entire contents of which are hereby incorporated by reference.

### BACKGROUND

1. Technical Field

The present invention disclosed herein relates to an apparatus for treating a substrate, and more particularly, to an apparatus for treating plasma and a method for cleaning the same.

2. Description of Related Art

Various processors are needed to fabricate a semiconductor substrate in the various processes (e.g., thin layer deposition, etching, and cleaning), plasma is generated from a process gas and supplied to a semiconductor substrate such as a wafer.

In a plasma enhanced chemical vapor deposition (PECVD) process that is typically performed in a thin layer deposition, after injecting a process gas comprising a reaction gas and an inert gas into a reaction chamber, a high-frequency power is applied to an electrode disposed inside the reaction chamber to generate the plasma from the process gas. Reaction gas ions in the plasma are deposited on the substrate to form a thin layer. Another process is plasma atomic layer deposition (ALD), which forms a thin layer having improved step coverage at a lower temperature than layers formed using the PECVD process. In the plasma ALD process, after placing a wafer in a vacuum chamber, a first reaction gas and a second reaction gas are alternately injected in the vacuum chamber to form an atomic layer on the substrate.

While performing a thin layer deposition process in the reaction chamber, a thin layer can be deposited on undesirable regions such as a heater of the deposition equipment, an inner wall in the reaction chamber, and a top surface of a susceptor that supports the substrate. Since the deposits in these regions can cause defects on the substrate, a cleaning process is needed.

The cleaning process for removing the deposits includes a wet cleaning process. However, the wet cleaning process needs to be performed after disassembling an apparatus for treating plasma. Moreover, the process becomes more complex, and also takes time to reassemble the apparatus for treating plasma after cleaning. Consequently, the time that an apparatus may be used for deposition is reduced and productivity decreases. In a case of depositing a thick dielectric layer, the operating time of an apparatus is further reduced. Accordingly, an in-situ cleaning process that can perform a cleaning process in a short time is needed.

### SUMMARY OF THE INVENTION

According to an embodiment of the present invention, an apparatus for treating plasma includes an inner chamber, an outer chamber receiving the inner chamber and including a gas supplier that supplies a gas into the inner chamber, an inner electrode disposed in the inner chamber, and a plasma generator supplying power independently to the inner electrode and the inner chamber.

In some embodiments, the plasma generator may include a first high-frequency generator supplying a high-frequency power to the inner electrode, and a second high-frequency generator supplying a high-frequency power to the inner chamber. The plasma generator may further include a first matcher disposed between the inner electrode and the first high-frequency generator, an second matcher disposed between the inner chamber and the second high-frequency generator. The plasma generator may further include a controller controlling the first high-frequency generator and the second high-frequency generator such that the first high-frequency generator is operated when the gas in a process gas supplied into the inner chamber, and the first high-frequency generator and the second high-frequency generator are operated when the gas is a cleaning gas supplied into the inner chamber.

In other embodiments, the inner chamber may be formed of metal. The inner chamber may include a susceptor receiving a substrate, and a cover disposed on the susceptor to define a space where a process is performed. The susceptor may include a heater heating the substrate. The susceptor may receive a high-frequency power when the gas is a cleaning gas is applied to the inner chamber. The susceptor is movable in a substantially vertical direction for loading and unloading the substrate into or from the inner chamber.

In still other embodiments, each of the inner chamber and the outer chamber may include a top portion having an inlet port and an outlet port for the gas, and the inner electrode is disposed at the center of the inner chamber such that the gas is moved along the inner surface of the inner chamber.

In other embodiments, the inner chamber and the outer chamber may be insulated from each other, a space therebetween may maintain a vacuum.

In other embodiments, the gas is a process gas including a source gas that is supplied to form a thin layer on a substrate, and a cleaning gas comprising one selected from the group consisting of BClₓ, SiClₓ, SF₆, NF₃, Cl₂, SiBr₄, C₄F₆, C₄F₈, CF₅, CHF₃, and a combination thereof.

In still other embodiments of the present invention, a method for cleaning the apparatus for treating plasma comprising an inner chamber, an outer chamber receiving the inner chamber and including a gas supplier that supplies gas into the inner chamber, an inner electrode disposed in the inner chamber, and a plasma generator supplying power independently to the inner electrode and the inner chamber includes supplying a process gas into the inner chamber to form a thin layer on a substrate seated inside the inner chamber, supplying a cleaning gas into the inner chamber, and supplying high-frequency power independently to the inner electrode and the inner chamber, and using plasma generated from the cleaning gas to clean the inner chamber.

In some embodiments, the method may further include, before the supplying of the cleaning gas into the inner chamber, replacing the substrate having the thin layer with a dummy wafer.

In other embodiments, the cleaning gas may comprises one selected from the group consisting of BClₓ, SiClₓ, SF₆, NF₃, Cl₂, SiBr₄, C₄F₆, C₄F₈, CF₅, CHF₃, and a combination thereof.

In still other embodiments, the high-frequency power supplied to the inner chamber may be higher than the high-frequency power supplied to the inner electrode.

### BRIEF DESCRIPTION OF THE FIGURES

Non-limiting and non-exhaustive embodiments of the present invention will be described with reference to the following figures, wherein like reference numerals refer to like part throughout the various figures unless otherwise specified. In the figures:

FIG. 1 is a view of an apparatus for treating plasma according to an embodiment of the present invention; and

FIG. 2 is a flowchart of a process according to an embodiment of the present invention, which may be implemented in the apparatus for treating plasma of FIG. 1.

### DETAILED DESCRIPTION OF PREFERRED EMBODIMENT

Preferred embodiments of the present invention will be described below in more detail with reference to the accompanying drawings. The present invention may, however, be embodiment in different forms and should not be constructed as limited to embodiments set forth herein. Rather, embodiments are provided so that this disclosure will be thorough and complete, and will fully convey the scope of the present invention to those skilled in the art.

Terms such as first and second are used to describe a high-frequency generator and a matcher, but the high-frequency generator and the matcher are not limited to the above terms. The terms are merely used to distinguish a predetermined high-frequency generator and matcher from another high-frequency generator and matcher. Components in the drawings are exaggerated for clarity.

Terms for a process gas and a cleaning gas of the present invention include a gas state and a vapor state. Accordingly, the present invention is not limited to the above terms.

Structure of Apparatus for Treating Plasma

A plasma enhanced atomic layer deposition (PEALD) apparatus is an exemplary apparatus for treating plasma. Embodiments of the present invention can be applied to other apparatuses performing a process using plasma besides the PEALD apparatus. Additionally, a wafer W is described as an example of a substrate, but the substrate can be a glass substrate.

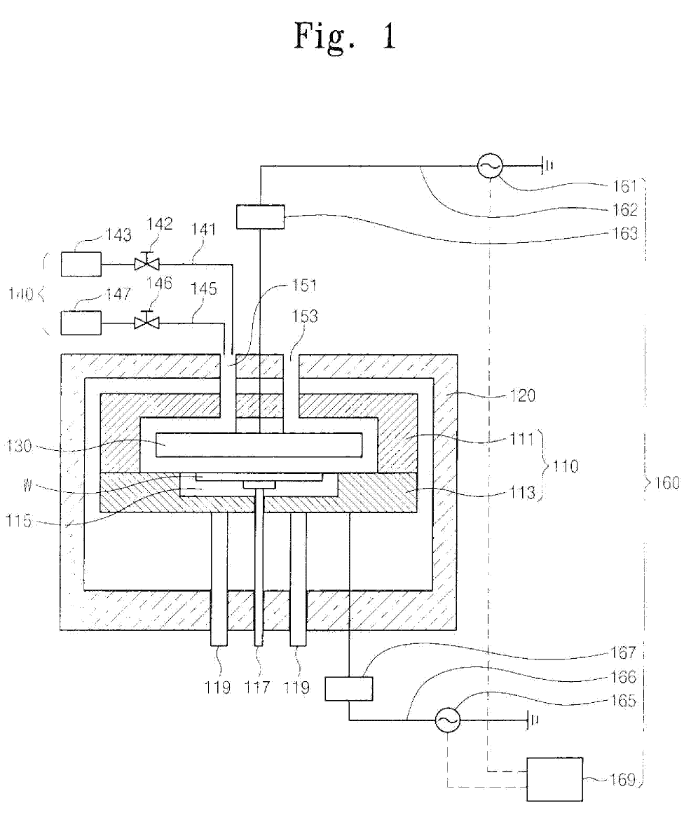

FIG. 1 is a view of an apparatus for treating plasma according to an embodiments of the present invention. The apparatus for treating plasma includes the inner chamber 110, an outer chamber 120, an inner electrode 130, and a plasma generator 160.

The inner chamber 110 includes susceptor 113 sustaining the wafer W and a cover 111 disposed on the susceptor 113 to define the space where the process is performed. The susceptor 113 and the cover 111 contract each other to define the space where the process is performed, and are separated when the wafer W is loaded or unloaded. The inner chamber 110 is formed of a metal material. The susceptor 113 is electrically connected to the cover 111 when they contact each other. The susceptor 113 can include a heater 115 that heats the wafer W while a process is performed. A position regulator 119 moving the susceptor 113 up and down, in a substantially vertical direction, can be disposed below the susceptor 113, and the wafer supporter 117 passing through the susceptor 113 can be disposed substantially centered between the position regulators 119.

The inner chamber 110 of the apparatus for treating plasma includes a volume to turn on/off plasma while performing an ALD process. The volume of the inner chamber 110 where a process is performed needs to be adapted to, e.g., small enough, to stabilize the changing process atmosphere such as the maintenance and on/off of the plasma can be easily achieved.

The outer chamber 120 receives the inner chamber 110. The outer chamber 120 may be formed of a metal material or ceramic, such as quartz. The inner chamber 110 and the outer chamber 120 are spaced a predetermined distance apart from each other to be insulated such as that the space therebetween can maintain a vacuum. An inlet port 151 and the outlet port 153 for a process gas or a cleaning gas pass through the inner chamber 110 and the outer chamber 120. The outer chamber 120 further includes a gas supplier 140 supplying the process gas and the cleaning gas into the inner chamber 110.

The gas supplier 140 includes gas supply pipes 141 and 145 supplying the process gas or the cleaning gas from an external gas storage (not shown) into the inner chamber 110. A plurality of the gas supply pipes 141 and 145 are provided, and also supply respectively different gases. For example, the gas supply pipe 141 supplies the process gas and the gas supply pipe 145 supplies the cleaning gas. Additionally, the gas supply pipe 141 may supply different gases. The process gas includes a source gas and a purge gas. The source gas, that is supplied to deposit a thin layer on a wafer, may include different reactions gases, such as a first reaction gas having a metal source, and a second reaction gas such as O₂, N₂, H₂O, and NH₃ providing oxygen and nitrogen to the metal source. Additionally, the cleaning gas includes one selected from the group consisting of BClₓ, SiClₓ, SF₆, NF₃, Cl₂, SiBr₄, C₄F₆, C₄F₈, CF₅, CHF₃, or a combination thereof. On/off valves 142 and 146 open and close the inside of the gas supply pipes 141 and 145 and flow meters 143 and 147 adjust a flow a supplied gas can be installed with the gas supply pipes 141 and 145, respectively.

An inner electrode 130 is disposed inside the inner chamber 110. The inner electrode may be formed of a metal material. The inner electrode 130 may be disposed substantially at the center of the inner chamber 110 such that the process gas or the cleaning gas moves along the inner surface of the chamber 110.

The plasma generator 160 generates plasma from the process gas or the cleaning gas that is supplied to the inner chamber 110. The plasma generator 160 includes a first high-frequency generator 161 and a second high-frequency generator 165 that supply power to the inner electrode 130 and the inner chamber 110, respectively. The first high-frequency generator 161 applies a high-frequency power to the inner electrode 130 through a first high-frequency line 162. The second high-frequency generator 165 can be connected to the susceptor 113 of the inner chamber 110 through a second high-frequency line 166.

The plasma generator 160 further includes a first matcher 163 disposed between the first high-frequency generator 161 and the inner electrode 130, and a second matcher 167 disposed between the second high-frequency generator 165 and the inner chamber 110. Because of the first and second matchers 163 and 167, a high-frequency power generated from the first and second high-frequency generators 161 and 165 can be applied without the loss to the inner electrode 130 and the inner chamber 110 under an optimized condition.

The plasma generator 160 further includes a controller 169 controlling the first high-frequency generator 161 and the second high-frequency generator 165. The controller 169 operates the first high-frequency generator 161 when the process gas is supplied to the inner chamber 110, and operates the first and second high-frequency generators 161 and 165 when the cleaning gas is supplied to the inner chamber 110. The high-frequency generators 161 and 165 can be appropriately selected according to the process performed in the inner chamber 110.

Method for Cleaning Apparatus for Treating Plasma

Hereinafter, a method for cleaning the apparatus for treating plasma will be described. Since the apparatus described for treating plasma is a plasma ALD apparatus, the following thin layer formation process is performed using an ALD process. However, the present invention is not limited thereto, other apparatus and processes may be implemented according to embodiments of the present invention.

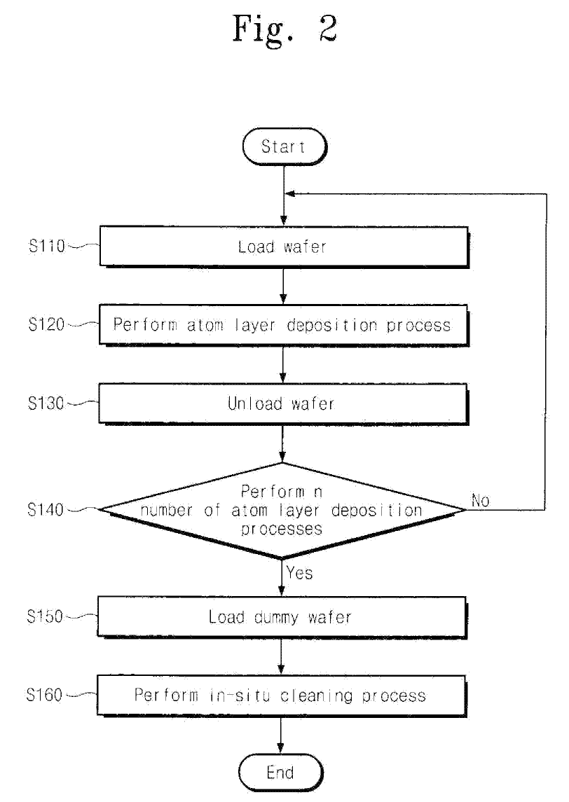

FIG. 2 is a flowchart of a process according to an embodiment of the present invention, which may be implemented in the apparatus for treating plasma of FIG. 1. The apparatus for treating plasma performs a thin layer formation process in block S120 and an in-situ cleaning process in block S160.

Referring to FIGS. 1 and 2, a wafer W is loaded into the inner chamber 110 in block S110. The position regulator 119 lowers the susceptor 113, and a transfer device (not shown) moves the wafer to the wafer supporter 117 through a gate (not shown) of the outer chamber 120. The susceptor 113 rises and the wafer W is seated on the susceptor 113. The susceptor 13 and the cover 110 contact each other to define the space where a process is performed. When the gate of the outer chamber 120 is closed, the space between the inner chamber 110 and the outer chamber 120 is held under a vacuum.

A plasma ALD process is performed in bock S120. The plasma ALD process of block S120 can be applied to depositions of various materials such as a chemical compound semiconductor, a silicon oxide layer, a metal oxide layer, and a metal nitride layer. Metal an nonmetal are alternately used as a reaction materials. According to an ALD process, if it possible to completely react with a metal such that a metal oxide layer or a metal nitride layer can be formed. Moreover, in the ALD process, it is possible to control a thickness of a thin layer and achieve good step coverage.

A high-k dielectric layer such as HfO₂, Al₂O₃, and ZrO₃ can be formed using the ALD process of block S120. The first reaction gas including a metal source, and second reaction gas are alternately supplied through the gas supply pipe 141 to form the dielectric layer. A purge gas is supplied between the supply of the first reaction gas and the supply of the second reaction gas. The purge gas can be continuously supplied while performing the ALD process. The purge gas can be gas such as Ar, N₂, and He. When the process gas including the first reaction gas, the second reaction gas, and the purse gas are supplied to the inner chamber 110, the controller 169 selects the first high-frequency generator 161. The selected first high-frequency generator 161 applies a high-frequency power to the inner electrode 130 through the high-frequency line 162. At this point, the inner chamber 110 is grounded. Because of the first matcher 163 disposed between the first high-frequency generator 161 and the inner electrode 130, the high-frequency power generated from the first high-frequency generator 161 is applied substantially without loss to the inner electrode 130 under an optimized condition Because of the high-frequency power applied to the inner electrode 130, plasma is generated from the process gas, and reaction gas ions in the plasma are deposited to form a thin layer.

Once the ALD processor block S120 is completed, the wafer W is unloaded from the apparatus for treating plasma 100 in block S130. The wafer unloading of block S130 can be performed identical to the wafer loading of block S110.

When the wafer W having the thin layer is unloaded, a new wafer is loaded to perform an ALD process. Likewise, the wafer loading of block S110, the ALD process of block S120, and the wafer unloading of block S130 are performed sequentially and repeatedly.

When performing an ALD process, deposits can be formed on the surface of the wafer W and the inner surface (e.g., the top surface of the susceptor 113 and the side of the cover 111) of the inner chamber 110. The deposit an cause defects such as particles on the surface of the wafer W. When the ALD process is performed repeatedly, the deposit accumulates. Therefore, after the predetermined number of ALD processes, the inner chamber needs to be cleaned. The n number of ALD processes can be determined by considering kinds and thickness of the atomic layer.

When the n^{th} ALD process is determined at block S140, a dummy wafer is loaded into the inner chamber 110 at block S150. While the ALD process is performed at block S120, since deposit is not formed on the surface of the susceptor 113 where the wafer W is disposed, the surface of the susceptor 113 can be protected from the deposit due to the dummy wafer during the cleaning process of block S160.

When the dummy wafer loading of block S150 is completed, an in-situ cleaning process of block S160 is performed. A cleaning gas supplied from the gas supply pipe 145 is supplied into the inner chamber 110 through the inlet port 151. The cleaning gas includes one selected from the group consisting of BClₓ, SiClₓ, SF₆, NF₃, Cl₂, SiBr₄, C₄F₆, C₄F₈, CF₅, CHF₃, or a combination thereof. The controller 169 selects the first high-frequency generator 161 and the second high-frequency generator 165. The first high-frequency generator 161 applies a high-frequency power to the inner electrode 130 through a high-frequency line 162. The second high-frequency generator 165 can be connected to the susceptor 113 of the inner chamber 110 through a high-frequency line 166. Since the deposition rate is greater on the inner wall of the inner chamber 110 than the inner electrode to which a high-frequency power is applied during an ALD process of block S120, higher frequency power is applied on the inner chamber 110 than the inner electrode 130 during the cleaning process. The strength of the applied high-frequency power is determined by considering the n number of ALD processes and atomic layer characteristics such as kinds and thickness.

The second high-frequency generator 165 is connected to the susceptor 113 through the high-frequency line 166. The cover 111 and the susceptor 113 are formed of a metal material. Therefore, the high-frequency power applied to the susceptor 113 can be applied to the cover 111. The first an second matchers 163 and 167 are respectively disposed between the first high-frequency generator 161 and the inner electrode 130, and the second high-frequency generator 165 and the inner chamber 110. Thus, the high-frequency power generated from the first and second high-frequency generators 161 and 165 is applied substantially without loss to the inner electrode 130 and the inner chamber 110 under an optimized condition.

Plasma of the cleaning gas is generated from the high-frequency power applied to the inner electrode 130 and the inner chamber 110, respectively. Due to the plasma, the deposits formed on the inner wall of the inner shamber 110 is etched and dischagred together with the cleaning gas through the outer porti 153.

Once the cleaning process of block S160 is completed, a dummy wafer is unloaded and the wafer loading of block S110 is performed for carrying out the ALD process of block S120.

According to an embodiment of the present invention, a high-frequency power is directly applied into the inner chamber to physically receive the deposits, which can be difficult to remove using a chemically dry etching process. Additionally, without disassembling the apparatus for treating plasma, the cleaning process can be performed.

According to an embodiment of the present invention, by using an in-situ cleaning process, the cleaning process can be performed in a short time. Therefore, a plasma operating time may be increased, and productivity improved.

According to an embodiment of the present invention, by directly supplying a high-frequency power to the inner chamber, the deposit formed on the inner wall of the inner chamber can be removed at a substantially uniform etching speed. Therefore, the damage of the apparatus can be substantially prevented during an in-situ cleaning process. Moreover, the high-k dielectric layer can be easily removed, which can be difficult to remove using a chemically dry etching process.

The above-disclosed subject matter is to be considered illustrative, and not restrictive, an the appended claims are intended to cover all such modifications, enhancements, and embodiments, which all within the spirit and scope of the disclosure Thus, to the maximum extent allowed by law, the scope of the present invention is to be determined by the broadest permissible interpretation of the following claims and their equivalents, and shall not be restricted or limited by the foregoing detailed description.

What is claimed is:

1. An apparatus for treating plasma, the apparatus comprising:
an inner chamber;
an outer chamber receiving the inner chamber and including a gas supplier than supplies gas into the inner chamber;
an inner electrode disposed in the inner chamber; and
a plasma generator supplying power independently to the inner electrode and the inner chamber.

2. The apparatus of claim 1, wherein the plasma generator comprises:
a first high-frequency generator supplying a high-frequency power to the inner electrode; and
a second high-frequency generator supplying a high-frequency power to the inner chamber.

3. The apparatus of claim 2, wherein the plasma generator further comprises:
a first matcher disposed between the inner electrode and the first high-frequency generator; and
a second matcher disposed between the inner chamber and the second high-frequency generator.

4. The apparatus of claim 2, wherein the plasma generator further comprises a controller controlling the first high-frequency generator and the second high-frequency generator such that the first high-frequency generator is operated when the gas is a process gas supplied into the inner chamber, and the first high-frequency generator and the second high-frequency generator are operated where the gas is a cleaning gas supplied into the inner chamber.

5. The apparatus of claim 1, wherein the inner chamber is formed of metal.

6. The apparatus of claim 5, wherein the inner chamber comprises:
a susceptor receiving a substrate; and
a cover disposed on the susceptor to define a space where a process is performed.

7. The apparatus of claim 6, wherein the susceptor comprises a heater heating the substrate.

8. The apparatus of claim 6, wherein the susceptor is supplied with a high-frequency power when the gas is a cleaning gas supplied into the inner chamber.

9. The apparatus of claim 6, wherein the susceptor is movable in a substantially vertical direction for loading or unloading the substrate into or from the inner chamber.

10. The apparatus of claim 1, wherein each of the inner chamber and the outer chamber comprises a top portion having an inlet port and an outlet port for the gas, and the inner electrode is disposed at the center of the inner chamber such that the gas is moved along the inner surface of the inner chamber.

11. The apparatus of claim 1, wherein the inner chamber and the outer chamber are insulated from each other, and a space therebetween maintains a vacuum.

12. The apparatus of claim 1, wherein the gas is a process gas including source gas that is supplied to form a thin layer on a substrate, and a cleaning gas comprising one selected from the group consisting of BClₓ, SiClₓ, SF₆, NF₃, Cl₂, SiBr₄, C₄F₆, C₄F₈, CF₅, CHF₃, and a combination thereof.

13. A method for cleaning an apparatus for treating plasma comprising an inner chamber, an outer chamber receiving the inner chamber and including a gas supplier that supplies a gas into the inner chamber, an inner electrode disposed in the inner chamber, and a plasma generator supplying power independently to the inner electrode and the inner chamber, the method comprising:
supplying a process gas into the inner chamber to form a thin layer on a substrate seated inside the inner chamber;
supplying a cleaning gas into the inner chamber; and
supplying high-frequency power independently to the inner electrode and the inner chamber, and using plasma generated from the cleaning gas to clean the inner chamber.

14. The method of claim 13, further comprising, before the supplying of the cleaning gas into the inner chamber, replacing the substrate having the thin layer with a dummy wafer.

15. The method of claim 13, wherein the cleaning gas comprises one selected from the group consisting of BClₓ, SiClₓ, SF₆, NF₃, Cl₂, SiBr₄, C₄F₆, C₄F₈, CF₅, CHF₃, and a combination thereof.

16. The method of claim 13, wherein the high-frequency power supplied to the inner chamber is higher than the high-frequency power supplied to the inner electrode.
